(19) United States
(12) Patent Application Publication
(10) Pub. No.: US 2025/0022780 A1
(43) Pub. Date: Jan. 16, 2025

(54) Semiconductor Devices and Methods for Manufacturing Thereof

(71) Applicant: Infineon Technologies AG, Neubiberg (DE)

(72) Inventor: Thomas Bemmerl, Schwandorf (DE)

(21) Appl. No.: 18/768,582

(22) Filed: Jul. 10, 2024

(30) Foreign Application Priority Data
Jul. 13, 2023 (DE) 102023118653.1

(51) Int. Cl. H01L 23/495; H01L 21/48; H01L 21/56; H01L 23/00; H01L 23/31

(52) U.S. Cl. CPC H01L 23/49555; H01L 21/4842; H01L 21/565; H01L 23/3135; H01L 23/49562; H01L 24/48; H01L 2224/48245; H01L 2924/13091

(57) ABSTRACT

A semiconductor device includes an encapsulation material at least partially encapsulating a semiconductor component of the semiconductor device. The semiconductor device further includes a lead protruding out of the encapsulation material and extending along a longitudinal axis, the lead comprising a twisted section along which the lead is twisted around the longitudinal axis. The twisted section of the lead is encapsulated in the encapsulation material, or the twisted section of the lead is external to the encapsulation material and provides an increased clearance distance between a residual dambar portion of the lead and an adjacent lead.

### TECHNICAL FIELD

The present disclosure relates to semiconductor devices. In addition, the present disclosure relates to methods for manufacturing semiconductor devices.

### BACKGROUND

Conventional semiconductor packages may comply with predefined specifications regarding their size, lead count and/or lead dimensions. The predefined specifications may result in limited electrical and isolation performance of the device, in particular with regard to creepage and clearance distances between leads of the device. Manufacturers and developers of semiconductor devices are constantly striving to improve their products. In particular, it may be desirable to provide semiconductor devices with an improved electrical and isolation performance. It may further be desirable to provide suitable methods for manufacturing such semiconductor devices.

### SUMMARY

An aspect of the present disclosure relates to a semiconductor device. The semiconductor device comprises an encapsulation material at least partially encapsulating a semiconductor component of the semiconductor device. The semiconductor device further comprises a lead protruding out of the encapsulation material and extending along a longitudinal axis, the lead comprising a twisted section along which the lead is twisted around the longitudinal axis. The twisted section of the lead is encapsulated in the encapsulation material, or the twisted section of the lead is external to the encapsulation material and provides an increased clearance distance between a residual dambar portion of the lead and an adjacent lead.

A further aspect of the present disclosure relates to a semiconductor device. The semiconductor device comprises an encapsulation material at least partially encapsulating a semiconductor component of the semiconductor device. The semiconductor device further comprises a first lead protruding out of the encapsulation material. A portion of the first lead external to the encapsulation material has a thickness measured in a direction perpendicular to a main surface of the encapsulation material and a width measured in a direction parallel to the main surface of the encapsulation material. The thickness of the portion of the first lead is greater than the width of the portion of the first lead.

A further aspect of the present disclosure relates to a method for manufacturing a semiconductor device. The method comprises an act of providing a lead extending along a longitudinal axis. The method further comprises an act of twisting a section of the lead around the longitudinal axis, thereby providing a twisted section of the lead. The method further comprises an act of at least partially encapsulating a semiconductor component of the semiconductor device in an encapsulation material, wherein the lead at least partially protrudes out of the encapsulation material. The twisted section of the lead is encapsulated in the encapsulation material, or the twisted section of the lead is external to the encapsulation material and provides an increased clearance distance between a residual dambar portion of the lead and an adjacent lead.

A further aspect of the present disclosure relates to a method for manufacturing a semiconductor device. The method comprises an act of at least partially encapsulating a lead and a semiconductor component of the semiconductor device in an encapsulation material. A portion of the lead external to the encapsulation material has a thickness measured in a direction perpendicular to a main surface of the encapsulation material and a width measured in a direction parallel to the main surface of the encapsulation material. The thickness of the portion of the lead is greater than the width of the portion of the lead.

### BRIEF DESCRIPTION OF THE DRAWINGS

The accompanying drawings are included to provide a further understanding of aspects. The drawings illustrate aspects and together with the description serve to explain principles of aspects. Other aspects and many of the intended advantages of aspects will be readily appreciated as they become better understood by reference to the following detailed description. The elements of the drawings are not necessarily to scale relative to each other. Like reference signs may designate corresponding similar parts.

FIG. 1 includes FIGS. 1A and 1B schematically illustrating a top view and a side view of a semiconductor device 100 in accordance with the disclosure.

FIG. 2 includes FIGS. 2A and 2B schematically illustrating a top view and a side view of a semiconductor device 200.

FIG. 3 schematically illustrates a perspective view of a lead with a twisted section that may be included in a semiconductor device in accordance with the disclosure.

FIG. 4 includes FIGS. 4A and 4B schematically illustrating side views of a semiconductor device 400 in accordance with the disclosure.

FIG. 5 includes FIGS. 5A and 5B schematically illustrating side views of a semiconductor device 500.

FIG. 6 includes FIGS. 6A and 6B schematically illustrating a top view and a side view of a semiconductor device 600.

FIG. 7 includes FIGS. 7A and 7B schematically illustrating a top view and a side view of a semiconductor device 700 in accordance with the disclosure.

FIG. 8 includes FIGS. 8A and 8B schematically illustrating a top view and a side view of a semiconductor device 800 in accordance with the disclosure.

FIG. 9 includes FIGS. 9A and 9B schematically illustrating a top view and a side view of a semiconductor device 900 in accordance with the disclosure.

FIG. 10 includes FIGS. 10A to 10C schematically illustrating a method for manufacturing and mounting a semiconductor device 1000 on a printed circuit board.

FIG. 11 schematically illustrates a side view of a molding tool that may be used in a method for manufacturing a semiconductor device in accordance with the disclosure.

FIG. 12 schematically illustrates a semiconductor device 1200 in accordance with the disclosure mounted on a printed circuit board.

FIG. 13 schematically illustrates a semiconductor device 1300 in accordance with the disclosure mounted on a printed circuit board.

FIG. 14 illustrates a flowchart of a method for manufacturing a semiconductor device in accordance with the disclosure.

FIG. 15 illustrates a flowchart of a method for manufacturing a semiconductor device in accordance with the disclosure.

### DETAILED DESCRIPTION

In the following detailed description, reference is made to the accompanying drawings, in which are shown by way of illustration specific aspects in which the disclosure may be practiced. In this regard, directional terminology, such as “top”, “bottom”, “front”, “back”, etc. may be used with reference to the orientation of the figures being described. Since components of described devices may be positioned in a number of different orientations, the directional terminology may be used for purposes of illustration and is in no way limiting. Other aspects may be utilized and structural or logical changes may be made without departing from the concept of the present disclosure. Hence, the following detailed description is not to be taken in a limiting sense, and the concept of the present disclosure is defined by the appended claims.

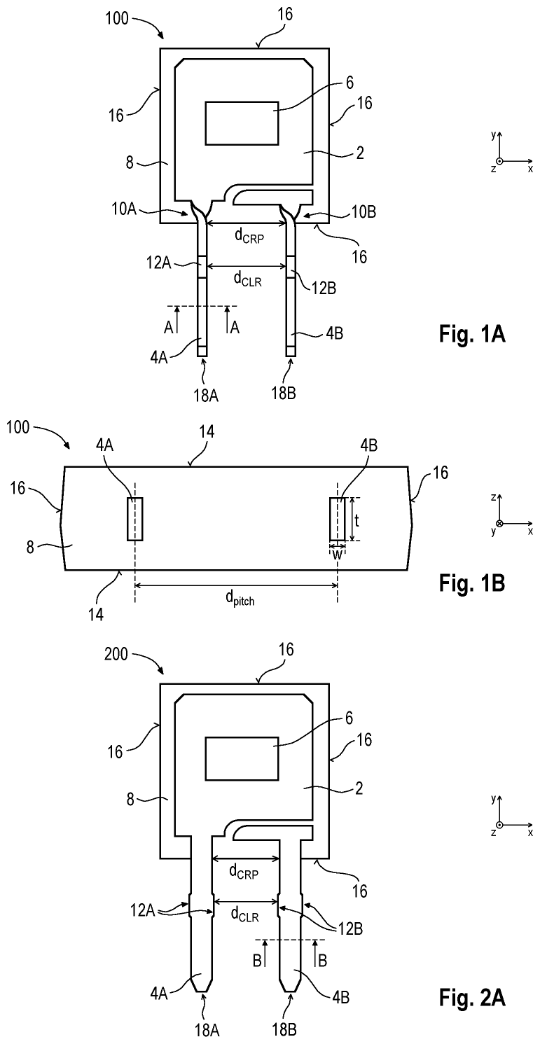

The semiconductor device 100 of FIGS. 1A and 1B may include a diepad 2, leads (or pins) 4A and 4B, a semiconductor component 6 and an encapsulation material 8 at least partially encapsulating one or more of these components. Each of the leads 4A and 4B may protrude out of the encapsulation material 8 and may extend along a longitudinal axis. In the illustrated example, the longitudinal axes (and thus the leads 4A and 4B) may extend in the y-direction. Each of the leads 4A and 4B may include a twisted section 10A and 10B, respectively, along which the respective lead may be twisted around the respective longitudinal axis. In the illustrated example, the twisted sections 10A and 10B may be arranged in the encapsulation material 8. It is noted that device components covered by the encapsulation material 8 may not be visible in practice, but are shown in FIG. 1A for illustrative purposes.

The diepad 2 and the leads 4A, 4B may be part of a leadframe. In the illustrated non-limiting example, one diepad 2 and two leads 4A, 4B are shown. In further examples, the numbers of diepads and leads may differ and may particularly depend on the specific type and functionality of the semiconductor device 100. The diepad 2 and the leads 4A, 4B may be fabricated from metals and/or metal alloys, in particular at least one of copper, copper alloys, nickel, iron nickel, etc. The lead 4A may be mechanically connected to the diepad 2. In this regard, the lead 4A and the diepad 2 may be made of a single piece of metal. Alternatively, the lead 4A may be connected to the diepad 2 via a fused connection. For example, the lead 4A may correspond to a power lead that may be connected to a power electrode of the semiconductor component 6.

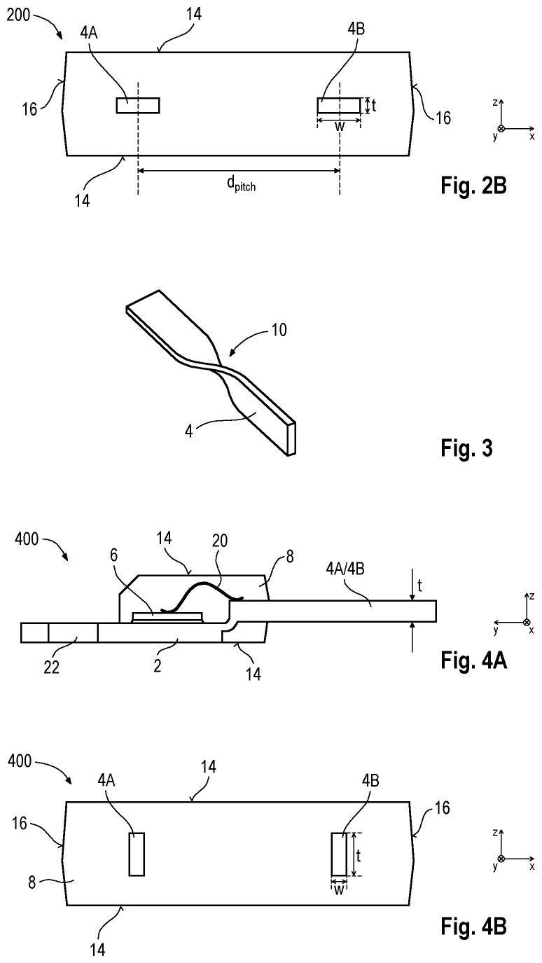

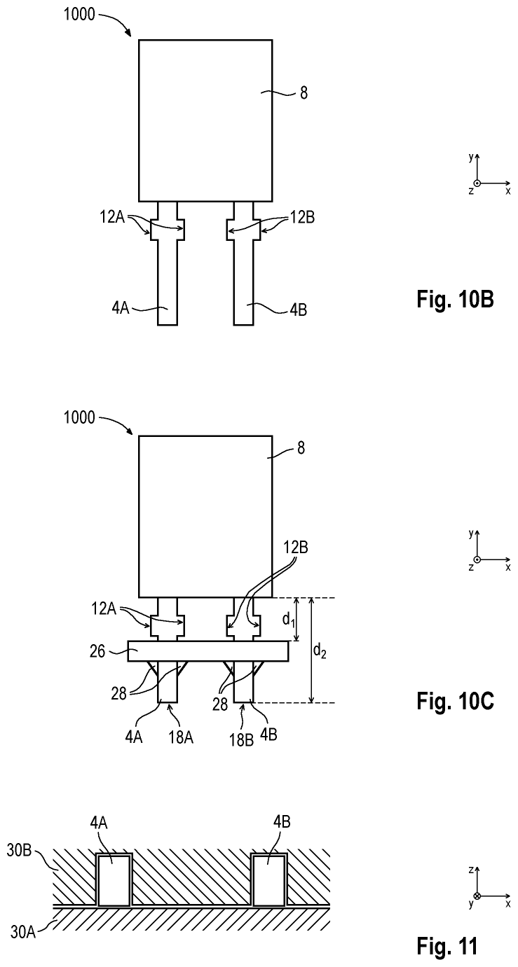

Each of the leads 4A and 4B may include one or more residual dambar portions 12A and 12B that may originate from a dambar that has been used and cut during a manufacturing process of the semiconductor device 100. An exemplary usage of a dambar in a manufacturing of a semiconductor device is shown and described later on in connection with FIGS. 10A to 10C. It is noted that another view of the dambar portions 12A and 12B from a different perspective or angle can be seen from FIG. 2A.

In the illustrated example, both leads 4A and 4B may be twisted around a longitudinal axis extending in the y-direction. In further examples, only one of the leads 4A and 4B may include a twisted section. For illustrative purposes, FIG. 3 shows a perspective view of a twisted section 10 of a lead 4, wherein the leads 4A and 4B of FIG. 1 may be twisted in a similar fashion. In the illustrated example of FIG. 1, the leads 4A and 4B may be twisted around the longitudinal axis by an angle of substantially ninety degrees.

FIG. 1A shows a clearance distance d_{CLR} between the leads 4A and 4B. A clearance distance d_{CLR} may be defined as shortest distance through the air between two conductive elements. In the illustrated example, the clearance distance d_{CLR} may be substantially constant along the entire lengths of the leads 4A and 4B outside of the encapsulation material 8. FIG. 1A further shows a creepage distance d_{CRP} between the leads 4A and 4B along a surface of the encapsulation material 8. A creepage distance d_{CRP} may be defined as shortest distance along the surface of a (solid) insulating material between two conductive parts.

In the illustrated example, the semiconductor device 100 may include a single semiconductor component 6. In further examples, the semiconductor device 100 may include two or even more semiconductor components. The semiconductor component 6 may include or may correspond to a semiconductor chip. Throughout this description, the terms “chip”, “semiconductor chip”, “die”, “semiconductor die” may be used interchangeably. The semiconductor chips may be manufactured from an elemental semiconductor material (e.g. Si) or from a wide band gap semiconductor material or a compound semiconductor material (e.g. SiC, GaN, SiGe, GaAs). The semiconductor chips may be of arbitrary types and may include integrated circuits with active electronic components and/or passive electronic components. The integrated circuits may be designed as logic integrated circuits, analog integrated circuits, mixed signal integrated circuits, power integrated circuits, memory circuits, integrated passives, etc.

In particular, the semiconductor chips may correspond to power semiconductor components and may thus be referred to as power semiconductor chips. In this context, the term “power semiconductor chip” may refer to a semiconductor chip providing at least one of high voltage blocking or high current-carrying capabilities. A power semiconductor chip may be configured for high currents having a maximum current value of a few Amperes, such as e.g. 10 A, or a maximum current value of up to or exceeding 100 A. Similarly, voltages associated with such current values may have values of a few Volts to a few tens or hundreds of Volts.

In a specific non-limiting example, the semiconductor component 6 may be a power transistor (e.g. a power MOSFET) including a gate electrode, a source electrode and a drain electrode. The drain electrode may e.g. be arranged on a surface of the semiconductor component 6 facing the diepad 2. The drain electrode may be electrically coupled to the diepad 2 and the lead 4A connected thereto. The gate electrode and the source electrode may e.g. be arranged on a surface of the semiconductor component 6 facing away from the diepad 2. For example, the gate electrode and the source electrode may be connected to the lead 4B and a further lead (not illustrated), respectively, by means of electrical connection elements. All three electrodes of the power transistor may be accessible from outside of the encapsulation material 8 via the leads.

The semiconductor device 100 may include electrical connection elements configured to provide an electrical connection between the semiconductor component 6 and one or both of the leads 4A and 4B. In the illustrated example, the electrical connection elements are not shown for the sake of simplicity. The electrical connection elements are not restricted to a specific type. For example, the electrical connection elements may include or may correspond to at least one of wires, clips, ribbons, etc.

The encapsulation material 8 may include or may be manufactured from at least one of an epoxy, a filled epoxy, a glass fiber filled epoxy, an imide, a thermoplast, a thermoset polymer, a polymer blend, a laminate, etc. Various techniques may be used for encapsulating the components of the semiconductor device 100 with the encapsulation material 8, for example at least one of compression molding, injection molding, powder molding, liquid molding, map molding, laminating, etc. In the illustrated example, the encapsulation material 8 may form a body or encapsulant having two opposite main surfaces 14 and multiple side surfaces 16 extending between the two main surfaces 14. Due to such packaging the semiconductor device 100 may also be referred to as semiconductor package. The leads 4A and 4B may at least partially protrude out of the encapsulation material 8 such that the encapsulated semiconductor component 6 may be electrically accessible from outside of the encapsulation material 8.

The lead 4B may include a portion external to the encapsulation material 8 and arranged between the twisted section 10B and an end section 18B of the lead 4B. As can be seen from the side view of FIG. 1B, this portion of the lead 4B may have a thickness “t” measured in a direction perpendicular to a main surface 14 of the encapsulation material 8 (i.e. in the z-direction in the illustrated example). In addition, the external portion of the lead 4B may have a width “w” measured in a direction parallel to a main surface 14 of the encapsulation material 8 (i.e. in the x-direction in the illustrated example). The thickness t may be greater than the width w. The same may hold true for the adjacent lead 4A which may be formed similar to the lead 4B. It is noted that the illustrated sections of the leads 4A and 4B may e.g. be taken along a line A-A shown in FIG. 1A.

The semiconductor device 200 of FIGS. 2A and 2B may be at least partially similar to the semiconductor device 100 of FIGS. 1A and 1B. In contrast to FIG. 1 none of the leads 4A and 4B may include a twisted section. As a result, the thickness t of the lead 4B is always smaller than the width w of the lead 4B, and the thickness t of the adjacent lead 4A is always smaller than the width w of the adjacent lead 4A. As can be seen from the top view of FIG. 2A a clearance distance d_{CLR} between the leads 4A and 4B may extend between the inner residual dambar portions 12A and 12B of the leads 4A and 4B. The sections of the leads 4A and 4B may be taken along a line B-B as shown in FIG. 2A.

A comparison between the semiconductor devices 100 and 200 shows that the clearance distance d_{CLR} between the leads 4A and 4B may be greater for the semiconductor device 100. In other words, the clearance distance d_{CLR} may be greater with the leads 4A and 4B being twisted (or including twisted portions 10A and 10B) than without the leads 4A and 4B being twisted. Note that the clearance distance d_{CLR} between the leads 4A and 4B in the semiconductor device 100 may be independent of the residual dambar portions 12A and 12B of the leads 4A and 4B. The comparison between the two examples further shows that the creepage distance d_{CRP} between the leads 4A and 4B along a surface of the encapsulation material 8 may be greater for the semiconductor device 100. Stated differently, the creepage distance d_{CRP} may be greater with the leads 4A and 4B being twisted than without the leads 4A and 4B being twisted.

It is to be noted that in the illustrated example of FIG. 1 both leads 4A and 4B may include a twisted section. In further examples, the clearance distance d_{CLR} and the creepage distance d_{CRP} between the leads 4A and 4B may also be increased by twisting only one of the leads 4A and 4B. It is further noted that in the illustrated example of FIG. 1 the leads 4A and 4B may be twisted by an angle of substantially ninety degrees which may maximize the clearance distance d_{CLR} and the creepage distance d_{CRP} between the leads 4A and 4B. In further examples, the twisting angle may be chosen smaller or greater than ninety degrees and may basically take an arbitrary value as long as the clearance distance d_{CLR} and/or the creepage distance d_{CRP} is increased compared to FIG. 2.

It is further to be noted that in the illustrated example of FIG. 1, the twisted sections 10A and 10B may be encapsulated in the encapsulation material 8. In further examples, the twisted sections 10A and 10B may be arranged external to the encapsulation material 8. In such cases, the creepage distance d_{CRP} between the leads 4A, 4B may be similar to the example of FIG. 2. However, twisted lead sections 10A and 10B arranged external to the encapsulation material 8 may still provide an increased clearance distance d_{CLR} between the leads 4A and 4B.

A pitch between the leads 4A and 4B may be defined as a distance d_{pitch} between the center of the lead 4A and the center of the lead 4B. As can be seen from the side views of FIGS. 1B and 2B, the pitch d_{pitch} between the leads 4A and 4B in the semiconductor device 100 may be similar to the pitch d_{pitch} between the leads 4A and 4B in the semiconductor device 200. In other words, the pitch d_{pitch} between the leads 4A and 4B may not necessarily depend on the leads 4A, 4B being twisted or not.

In the semiconductor device 100 of FIG. 1, the twisted sections 10A and 10B of the leads 4A and 4B may be configured to provide an interlocking between the encapsulation material 8 and the leads 4A and 4B. Such interlocking feature (or mold locking feature) may result in a firmer and more stable mechanical connection between the encapsulation material 8 and the leads 4A, 4B as compared to the example of FIG. 2 which does not provide such interlocking feature.

The semiconductor device 400 of FIGS. 4A and 4B may include some or all features of previously described semiconductor devices. The semiconductor device 400 may include a diepad 2, leads 4A and 4B, a semiconductor component 6 and an encapsulation material 8 at least partially encapsulating these components. Components covered by the encapsulation material 8 may not be visible in practice, but are shown in FIG. 4A for illustrative purposes. In the illustrated example, the semiconductor device 400 may further include one or more electrical connection elements 20 (such as e.g. bond wires, clips, ribbons, etc.) for providing an electrical connection between the semiconductor component 6 and one or more of the leads 4A and 4B. In addition, the diepad 2 (or a leadframe including the diepad 2) may optionally include a hole (or screw hole) 22. The semiconductor device 400 may be attached to another component (such as e.g. a heat sink) by means of a screw extending through the screw hole 22.

Each of the leads 4A and 4B may protrude out of the encapsulation material 8 and may extend along a longitudinal axis. In the illustrated example, the longitudinal axes (and thus the leads 4A and 4B) may extend in the y-direction. A portion of the lead 4B external to the encapsulation material 8 may have a thickness “t” measured in a direction perpendicular to a main surface 14 of the encapsulation material 8 (i.e. measured in the z-direction in the illustrated example). As can be seen from the side view of FIG. 4A, the thickness t of the lead 4B may be substantially similar to a thickness of the diepad 2 in the illustrated example.

Furthermore, the portion of the lead 4B external to the encapsulation material 8 may have a width “w” measured in a direction parallel to a main surface 14 of the encapsulation material 8 (i.e. measured in the x-direction in the illustrated example). As can be seen from the side view of FIG. 4B the thickness t of the external portion may be greater than its width w. The same may hold true for the adjacent lead 4A which may be similar to the lead 4B. In a specific, but non-limiting example, the thickness t may have a value of about 1.2 mm and the width w may have a value of about 0.6 mm. It is noted that the leads 4A and 4B of the semiconductor device 400 may not necessarily include twisted sections as e.g. described in connection with FIG. 1. Stated differently, the external portions of the leads 4A and 4B may be untwisted and may e.g. have a same geometry along their entire length.

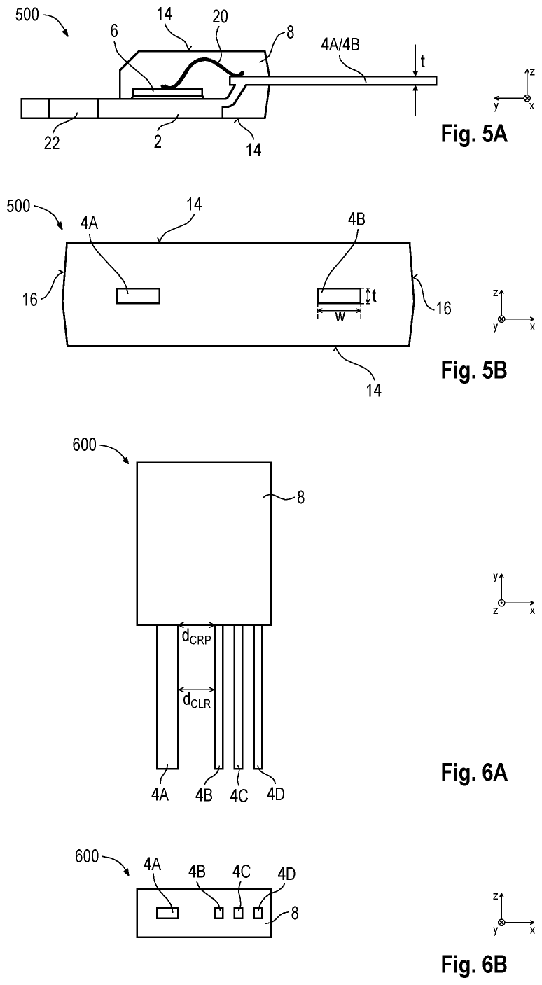

The semiconductor device 500 of FIGS. 5A and 5B may be at least partially similar to the semiconductor device 400 of FIGS. 4A and 4B. Compared to the example of FIG. 4, the leads 4A and 4B of FIG. 5 may be rotated (but not twisted) around the y-axis by an angle of about ninety degrees. Accordingly, a thickness t of the lead 4B measured in the z-direction is always smaller than a width w of the lead 4B measured in the x-direction. The same may hold true for the lead 4A which may be similar to the lead 4B. In a specific, but non-limiting example, the thickness t may have a value of about 0.6 mm and the width w may have a value of about 1.2 mm.

A comparison between the side views of FIG. 4B and 5B shows that the clearance distance d_{CLR} between the leads 4A and 4B may be greater for the semiconductor device 400. In addition, the creepage distance d_{CRP} between the leads 4A and 4B along a surface of the encapsulation material 8 may be greater for the semiconductor device 400. In the example of FIG. 4, the increased values for the clearance distance der and the creepage distance d_{CRP} are not provided by twisted sections of the leads 4A and 4B, as e.g. described in connection with FIG. 1, but may instead be based on the fact that the thicknesses t of the leads 4A and 4B are greater than the widths w of the leads 4A and 4B. Note that a pitch d_{pitch} between the leads 4A and 4B may be similar in FIGS. 4 and 5.

The semiconductor device 600 of FIGS. 6A and 6B may be at least partially similar to previously described semiconductor devices. In particular, the semiconductor device 600 may be similar to the semiconductor device 200 of FIG. 2. In contrast to FIG. 2 the semiconductor device 600 may include two additional leads 4C and 4D. Device components encapsulated in the encapsulation material 8 are not illustrated for the sake of simplicity.

In one example, the lead 4A may be a power lead electrically connected to a drain electrode of a power transistor chip embedded in the encapsulation material 8. In addition, the other leads 4B to 4D may include a gate lead electrically connected to a gate electrode of the power transistor chip and a source lead electrically connected to a source electrode of the power transistor chip. As can be seen from the side view of FIG. 6B, a thickness of the lead 4A measured in the z-direction is smaller than a width of the lead 4A measured in the x-direction.

The dimensions of the leads 4A to 4D and the encapsulation material 8 may depend on the specific type and functionality of the semiconductor device 600. A specific, but non-limiting example may be based on the following dimensions. The encapsulation body may have dimensions of about (x, y, z)˜(16.0, 21.0, 5.0) mm. A thickness of the diepad 2 in the z-direction (in case of a dual gauge leadframe) may have a value of about 2.0 mm. Each of the leads 4B to 4D may have a width in the x-direction of about 1.2 mm. A pitch between the leads 4B to 4D may have a value of about 2.54 mm. A thickness of the lead 4A in the z-direction may have a value of about 0.6 mm. The section of the lead 4A external to the encapsulation material 8 may have a length of about 20 mm measured in the y-direction. A maximum width of the power (e.g. drain) lead 4A measured in the x-direction may be defined by the values of the creepage distance d_{CRP} and the clearance distance d_{CLR} between the leads 4A and 4B. In a specific, but non-limiting case, the width of the lead 4A measured in the x-direction may be limited to a value of about 2 mm.

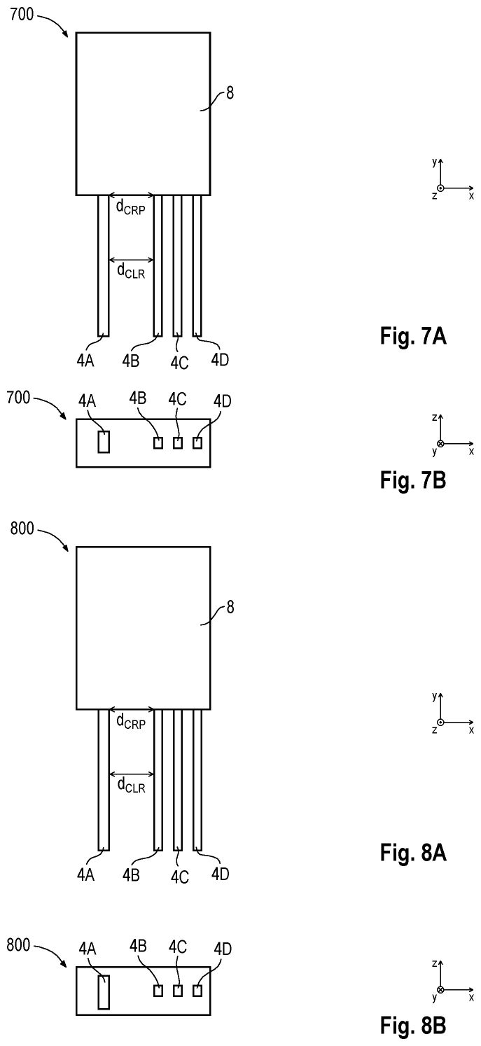

The semiconductor device 700 of FIGS. 7A and 7B may include some or all features of previously described semiconductor devices. For example, the semiconductor device 700 may be at least partially similar to the semiconductor device 600 of FIG. 6. In contrast to FIG. 6 a thickness of the lead 4A measured in the z-direction may be greater that a width of the lead 4A measured in the x-direction. Compared to the example of FIG. 6, the values of the creepage distance d_{CRP} and the clearance distance d_{CLR} between the leads 4A and 4B may thus be increased.

In one example, the increased values of the creepage distance d_{CRP} and the clearance distance d_{CLR} in the example of FIG. 7 may be provided by twisting the lead 4A, as e.g. described in connection with FIG. 1. In the illustrated example, a twisted section of the lead 4A may be encapsulated in the encapsulation material 8 and may thus be not visible. In a further example, the increased values of the creepage distance d_{CRP} and the clearance distance d_{CLR} may be provided by increasing the thickness of the lead 4A and reducing the width of the lead 4A, as e.g. described in connection with FIG. 4. Compared to the example of FIG. 6, the lead 4A of FIG. 7 may be rotated (but not twisted) by an angle of about ninety degrees. As can be seen from the side views of FIGS. 6B and 7B, the lead 4A of both examples may have a similar cross-sectional area in the x-z-plane. That is, the lead 4A of FIGS. 6 and 7 may be configured to carry electrical currents of similar strengths. Note that, in the example of FIG. 7, the thickness of the lead 4A in the z-direction may be greater than a thickness of the other leads 4B to 4D.

The semiconductor device 800 of FIGS. 8A and 8B may include some or all features of previously described semiconductor devices. In particular, the semiconductor device 800 may be similar to the semiconductor device 700 of FIG. 7. Compared to FIG. 7, a thickness of the lead 4A in the z-direction may be increased while the width of the lead 4A in the x-direction may be substantially similar. The values of the creepage distance d_{CRP} and the clearance distance d_{CLR} between the leads 4A and 4B may be similar in FIGS. 7 and 8. As can be seen from the side views of FIG. 7B and 8B, a cross-sectional area of the lead 4A may greater in the example of FIG. 8B. That is, the lead 4A of FIG. 8 may be configured to carry higher electrical currents than the lead 4A of FIG. 7.

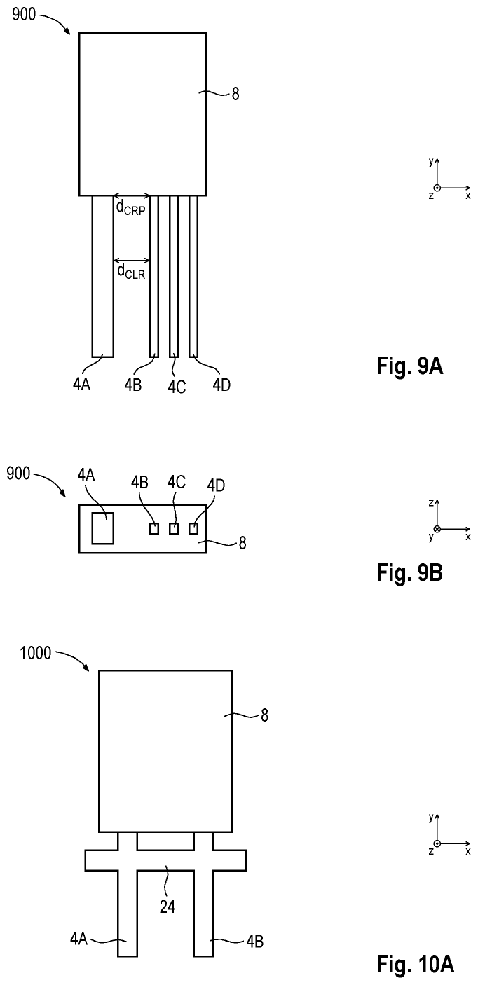

The semiconductor device 900 of FIGS. 9A and 9B may include some or all features of previously described semiconductor devices. In particular, the semiconductor device 900 may be similar to the semiconductor device 700 of FIG. 7. Compared to FIG. 7, each of the width of the lead 4A in the x-direction and the thickness of the lead 4A in the z-direction may be increased. In the illustrated example, the width of the lead 4A may have been increased in the left direction. The values of the creepage distance d_{CRP} and the clearance distance d_{CLR} between the leads 4A and 4B in FIGS. 7 and 9 may be similar. As can be seen from the side views of FIGS. 7B and 9B, a cross-sectional area of the lead 4A in FIG. 9B may greater than a cross-sectional area of the lead 4A in FIG. 7B. That is, the lead 4A of FIG. 9B may be configured to carry higher electrical currents than the lead 4A of FIG. 7B.

FIGS. 10A to 10C schematically illustrate a method for manufacturing and mounting a semiconductor device on a printed circuit board. In FIG. 10A a semiconductor device 1000 may be provided which may be at least partially similar to the semiconductor device 200 of FIG. 2. All previously performed method acts for manufacturing the arrangement of FIG. 10A (such as e.g. a molding act) are not described for the sake of simplicity.

The semiconductor device 1000 of FIG. 10A may still include a dambar 24 that may have been used in previous manufacturing acts. Dambars may be used in leadframe designs to facilitate a molding or encapsulation act and further to provide support for leads of the leadframe. During the encapsulation act the dambar may be configured to function as a clamping surface for the edges of the mold tool and as a barrier to prevent leakage or flashing of the mold material from the mold tool onto the leads. After the encapsulation act the dambar may be removed so that the leads may be physically and/or electrically individualized depending on their respective functionality.

In FIG. 10B the dambar 24 may be at least partially removed, for example using a punching tool (or cutting tool). The punching tool may not necessarily punch into the leads 4A and 4B when punching the dambar 24. Therefore, residual dambar portions 12A and 12B may remain after punching (or cutting) the dambar 24.

In FIG. 10C the semiconductor device 1000 may be mounted on an upper surface of a printed circuit board 26. In this regard, the leads 4A and 4B may be inserted in through holes of the printed circuit board 26, wherein an electrical connection between the leads 4A, 4B and electronic structures (such as e.g. conductor lines) of the printed circuit board 26 may be provided. The semiconductor device 1000 may be referred to as a through hole semiconductor device (or a through hole semiconductor package). The leads 4A and 4B arranged in the through holes may be fixed by means of a solder material 28 on the bottom surface of the printed circuit board 26.

As can be seen from FIG. 10C, when mounting the semiconductor device 1000 on the printed circuit board 26, the residual dambar portions 12A and 12B may define a distance d₁ between the encapsulation material 8 and the printed circuit board 26 as well as a distance d₂ between the encapsulation material 8 and the end sections 18A, 18B of the leads 4A, 4B.

FIG. 11 schematically illustrates a side view of a molding tool that may be used in a method for manufacturing a semiconductor device in accordance with the disclosure. The mold tool 30 may include a bottom part 30A and an upper part 30B. An upper surface of the bottom part 30A may be planar, while a bottom surface of the upper part 30B may include grooves in which the leads 4A and 4B may be placed during a molding act in which the encapsulation body 8 of the semiconductor device may be formed.

As previously described in connection with FIG. 10, dambars may provide a clamping surface for edges and/or the upper part 30B of the mold tool. In such case, the bottom surface of the upper part 30B may be planar. In contrast to this, if no dambars are used, the upper part 30B of the mold tool may require grooves for receiving the leads 4A and 4B during the molding act as shown in FIG. 11. The mold tool of FIG. 11 may therefore be used when molding an arrangement without dambars.

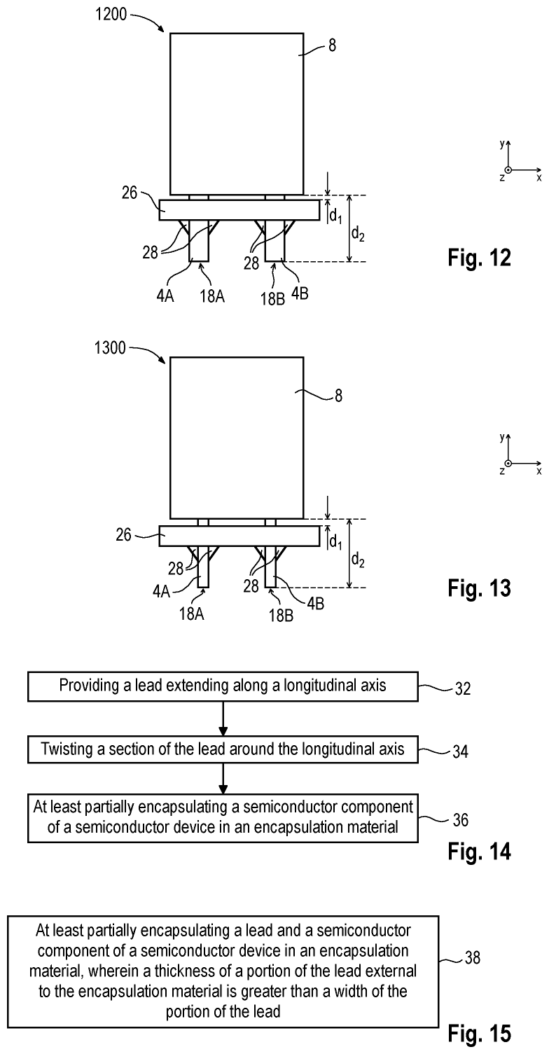

The semiconductor device 1200 of FIG. 12 may include some or all features of previously described semiconductor devices. Similar to the example of FIG. 10, the semiconductor device 1200 may correspond to a through hole semiconductor package. In this regard, it is to be noted that the concepts described herein are not restricted to a specific device or package type. In further examples, semiconductor devices in accordance with the disclosure may correspond to other device types, such as e.g. surface mounted devices (SMD). In contrast to FIG. 10 the leads 4A and 4B may not include residual dambar portions such that the distances di and de may be reduced. In this regard, the total length of the leads 4A and 4B measured in the y-direction may also be reduced which may result in an enhanced electrical performance. In particular, dynamic and/or static losses may be reduced due to a reduced lead inductivity and/or resistance. A reduced distance d₁ may result in a reduced inductance between the semiconductor device 1200 and the printed circuit board 26. This is because the electrical path of d₁ may be shortened. A longer electrical path for an AC current may cause a larger inductance. The closer the semiconductor device 1200 is sitting on the printed circuit board 26, the better the electrical performance due to reduced inductance. This may be achieved by leads 4A and 4B which do not include residual dambar portions.

The semiconductor device 1300 of FIG. 13 may be similar to the semiconductor device 1200 of FIG. 12. In contrast to FIG. 12 the leads 4A and 4B may be twisted or rotated around a longitudinal axis extending in the y-direction by an angle of about ninety degrees. Similar to FIG. 12 the semiconductor device 1300 may be a through hole semiconductor package providing reduced distances di and de. A comparison between the examples of FIGS. 12 and 13 shows that the distance between the encapsulation body 8 and the printed circuit board 26 may be reduced independent of the leads 4A and 4B being rotated (or twisted) or not.

FIGS. 14 and 15 illustrate flowcharts of methods for manufacturing semiconductor devices in accordance with the disclosure. The methods of FIGS. 14 and 15 are described in a general manner in order to qualitatively specify aspects of the present disclosure. The methods may include further aspects. For example, the methods may be extended by any aspect described herein in connection with other examples. In particular, the methods may be used for manufacturing previously described semiconductor devices in accordance with the disclosure.

FIG. 14 illustrates a first method for manufacturing a semiconductor device. At 32, a lead extending along a longitudinal axis may be provided. At 34, a section of the lead may be twisted around the longitudinal axis, thereby providing a twisted section of the lead. At 36, a semiconductor component of the semiconductor device may be at least partially encapsulated in an encapsulation material, wherein the lead at least partially protrudes out of the encapsulation material. The twisted section of the lead may be encapsulated in the encapsulation material, or the twisted section of the lead may be external to the encapsulation material and may provide an increased clearance distance between a residual dambar portion of the lead and an adjacent lead.

The act of twisting the section of the lead may be based on any suitable technique. In one example, twisting the section of the lead may be based on a coining technique, in particular a three dimensional coining technique. In further examples, twisting the lead may be based on folding, forging, etc. If the twisted section is embedded in the encapsulation material, a twisting of the lead may have been performed before a molding act. If the twisted section is arranged outside of the encapsulation material, a twisting of the lead may be performed before or after the molding act. Here, twisting the lead may be preferably performed before the molding act. In further examples, the twisted lead may have been arranged in a premolded leadframe before the encapsulation process. In such case, the premolded leadframe may be embedded in the encapsulation material.

FIG. 15 illustrates a second method for manufacturing a semiconductor device. At 38, a lead and a semiconductor component of the semiconductor device may be at least partially encapsulated in an encapsulation material. A portion of the lead external to the encapsulation material may have a thickness measured in a direction perpendicular to a main surface of the encapsulation material and a width measured in a direction parallel to the main surface of the encapsulation material. The thickness of the portion of the lead may be greater than the width of the portion of the lead.

Semiconductor devices in accordance with the disclosure and methods for manufacturing thereof may provide the following technical effects and may outperform conventional devices in various aspects.

Semiconductor devices in accordance with the disclosure may provide increased creepage distances and increased clearance distances between neighboring leads which may result in a higher isolation performance between the leads. In this regard, the clearance distance may not necessarily depend on residual dambar portions of the leads or an associated dambar cut precision.

Semiconductor devices in accordance with the disclosure may have package sizes, package footprints and lead pitches similar to conventional semiconductor devices. Accordingly, there may be no need for changing a design of customer boards onto which the semiconductor devices may be mounted.

Semiconductor devices in accordance with the disclosure may provide twisted leads having a reduced width as compared to conventional semiconductor devices. Due to such reduced widths of the leads, package designs with an increased lead count may be contemplated.

Semiconductor devices in accordance with the disclosure may include twisted lead sections arranged within the encapsulation material. The twisted sections may provide an interlocking between the encapsulation material and the respective lead. Such interlocking feature may result in a firmer mechanical connection between the encapsulation material and the lead.

### EXAMPLES

In the following, semiconductor devices in accordance with the disclosure and methods for manufacturing such semiconductor devices are described by means of examples.

Example 1 is a semiconductor device, comprising: an encapsulation material at least partially encapsulating a semiconductor component of the semiconductor device; and a lead protruding out of the encapsulation material and extending along a longitudinal axis, the lead comprising a twisted section along which the lead is twisted around the longitudinal axis, wherein: the twisted section of the lead is encapsulated in the encapsulation material, or the twisted section of the lead is external to the encapsulation material and provides an increased clearance distance between a residual dambar portion of the lead and an adjacent lead.

Example 2 is a semiconductor device according to Example 1, wherein a clearance distance between the lead and an adjacent lead is greater with the lead being twisted than without the lead being twisted.

Example 3 is a semiconductor device according to Example 1 or 2, wherein a creepage distance between the lead and an adjacent lead along a surface of the encapsulation material is greater with the lead being twisted than without the lead being twisted.

Example 4 is a semiconductor device according to one of the preceding Examples, wherein a pitch between the lead and an adjacent lead with the lead being twisted is similar or same to the pitch without the lead being twisted.

Example 5 is a semiconductor device according to one of the preceding Examples, wherein the lead is twisted around the longitudinal axis by an angle of substantially ninety degrees.

Example 6 is a semiconductor device according to one of the preceding Examples, wherein the twisted section of the lead is configured to provide an interlocking between the encapsulation material and the lead when the twisted section of the lead is encapsulated in the encapsulation material.

Example 7 is a semiconductor device according to one of the preceding Examples, wherein a clearance distance between the lead and an adjacent lead is independent of the residual dambar portion of the lead.

Example 8 is a semiconductor device according to one of the preceding Examples, wherein: a portion of the lead external to the encapsulation material and arranged between the twisted section and an end of the lead has a thickness measured in a direction perpendicular to a main surface of the encapsulation material and a width measured in a direction parallel to the main surface of the encapsulation material, and the thickness of the portion of the lead is greater than the width of the portion of the lead.

Example 9 is a semiconductor device according to one of the preceding Examples, further comprising: an adjacent lead protruding out of the encapsulation material and extending along a further longitudinal axis, wherein the adjacent lead comprises a further twisted section along which the adjacent lead is twisted around the further longitudinal axis.

Example 10 is a semiconductor device according to one of the preceding Examples, wherein the semiconductor device is a through hole semiconductor package.

Example 11 is a semiconductor device, comprising: an encapsulation material at least partially encapsulating a semiconductor component of the semiconductor device; and a first lead protruding out of the encapsulation material, wherein a portion of the first lead external to the encapsulation material has a thickness measured in a direction perpendicular to a main surface of the encapsulation material and a width measured in a direction parallel to the main surface of the encapsulation material, and wherein the thickness of the portion of the first lead is greater than the width of the portion of the first lead.

Example 12 is a semiconductor device according to Example 11, wherein: the first lead is a power lead mechanically connected to a diepad, and the first lead and the diepad are made of a single piece of metal.

Example 13 is a semiconductor device according to Example 12, wherein the first lead and the diepad have a same thickness.

Example 14 is a semiconductor device according to one of Examples 11 to 13, further comprising: a second lead adjacent to the first lead, wherein a thickness of the first lead is greater than a thickness of the second lead.

Example 15 is a semiconductor device according to one of Examples 11 to 14, wherein the portion of the first lead external to the encapsulation material has the same geometry along its entire length in the longitudinal direction.

Example 16 is a method for manufacturing a semiconductor device, the method comprising: providing a lead extending along a longitudinal axis; twisting a section of the lead around the longitudinal axis, thereby providing a twisted section of the lead; and at least partially encapsulating a semiconductor component of the semiconductor device in an encapsulation material, wherein the lead at least partially protrudes out of the encapsulation material, wherein: the twisted section of the lead is encapsulated in the encapsulation material, or the twisted section of the lead is external to the encapsulation material and provides an increased clearance distance between a residual dambar portion of the lead and an adjacent lead.

Example 17 is a method according to Example 16, wherein twisting the section of the lead is based on a three dimensional coining technique.

Example 18 is a method for manufacturing a semiconductor device, the method comprising: at least partially encapsulating a lead and a semiconductor component of the semiconductor device in an encapsulation material, wherein a portion of the lead external to the encapsulation material has a thickness measured in a direction perpendicular to a main surface of the encapsulation material and a width measured in a direction parallel to the main surface of the encapsulation material, and wherein the thickness of the portion of the lead is greater than the width of the portion of the lead.

As employed in this specification, the terms “connected”, “coupled”, “electrically connected”, and/or “electrically coupled” may not necessarily mean that elements must be directly connected or coupled together. Intervening elements may be provided between the “connected”, “coupled”, “electrically connected”, or “electrically coupled” elements.

Further, the word “over” used with regard to e.g. a material layer formed or located “over” a surface of an object may be used herein to mean that the material layer may be located (e.g. formed, deposited, etc.) “directly on”, e.g. in direct contact with, the implied surface. The word “over” used with regard to e.g. a material layer formed or located “over” a surface may also be used herein to mean that the material layer may be located (e.g. formed, deposited, etc.) “indirectly on” the implied surface with e.g. one or multiple additional layers being arranged between the implied surface and the material layer.

Furthermore, to the extent that the terms “having”, “containing”, “including”, “with”, or variants thereof are used in either the detailed description or the claims, such terms are intended to be inclusive in a manner similar to the term “comprising”. That is, as used herein, the terms “having”, “containing”, “including”, “with”, “comprising”, and the like are open-ended terms that indicate the presence of stated elements or features, but do not preclude additional elements or features. The articles “a”, “an”, and “the” are intended to include the plural as well as the singular, unless the context clearly indicates otherwise.

Moreover, the word “exemplary” is used herein to mean serving as an example, instance, or illustration. Any aspect or design described herein as “exemplary” is not necessarily to be construed as advantageous over other aspects or designs. Rather, use of the word exemplary is intended to present concepts in a concrete fashion. As used in this application, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the previous instances. In addition, the articles “a” and “an” as used in this application and the appended claims may generally be construed to mean “one or multiple” unless specified otherwise or clear from context to be directed to a singular form. Also, at least one of A and B or the like generally means A or B or both A and B.

Devices and methods for manufacturing devices are described herein. Comments made in connection with a described device may also hold true for a corresponding method and vice versa. For example, if a specific component of a device is described, a corresponding method for manufacturing the device may include an act of providing the component in a suitable manner, even if such act is not explicitly described or illustrated in the figures.

Although the disclosure has been shown and described with respect to one or multiple implementations, equivalent alterations and modifications will occur to others skilled in the art based at least in part upon a reading and understanding of this specification and the annexed drawings. The disclosure includes all such modifications and alterations and is limited only by the concept of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure which performs the function in the herein illustrated exemplary implementations of the disclosure. In addition, while a particular feature of the disclosure may have been disclosed with respect to only one of several implementations, such feature may be combined with one or multiple other features of the other implementations as may be desired and advantageous for any given or particular application.

1. A semiconductor device, comprising:
an encapsulation material at least partially encapsulating a semiconductor component of the semiconductor device; and
a lead protruding out of the encapsulation material and extending along a longitudinal axis, the lead comprising a twisted section along which the lead is twisted around the longitudinal axis, wherein:
the twisted section of the lead is encapsulated in the encapsulation material and there is no further twisted section on an outer portion of the lead which protrudes out of the encapsulation material, so that the outer portion of the lead extends along a plane different from a plane along which the most inner portion of the lead extends, or
the twisted section of the lead is external to the encapsulation material and provides an increased clearance distance between a residual dambar portion of the lead and an adjacent lead, wherein the twisted section is located between the encapsulation material and the residual dambar portion.

2. The semiconductor device of claim 1, wherein a clearance distance between the lead and an adjacent lead is greater with the lead being twisted than without the lead being twisted.

3. The semiconductor device of claim 1, wherein a creepage distance between the lead and an adjacent lead along a surface of the encapsulation material is greater with the lead being twisted than without the lead being twisted.

4. The semiconductor device of claim 1, wherein a pitch between the lead and an adjacent lead with the lead being twisted is similar or same to the pitch without the lead being twisted.

5. The semiconductor device of claim 1, wherein the lead is twisted around the longitudinal axis by an angle of substantially ninety degrees.

6. The semiconductor device of claim 1, wherein the twisted section of the lead is configured to provide an interlocking between the encapsulation material and the lead when the twisted section of the lead is encapsulated in the encapsulation material.

7. The semiconductor device of claim 1, wherein a clearance distance between the lead and an adjacent lead is independent of the residual dambar portion of the lead.

8. The semiconductor device of claim 1, wherein:
a portion of the lead external to the encapsulation material and arranged between the twisted section and an end of the lead has a thickness measured in a direction perpendicular to a main surface of the encapsulation material and a width measured in a direction parallel to the main surface of the encapsulation material, and
the thickness of the portion of the lead is greater than the width of the portion of the lead.

9. The semiconductor device of claim 1, further comprising:
an adjacent lead protruding out of the encapsulation material and extending along a further longitudinal axis,
wherein the adjacent lead comprises a further twisted section along which the adjacent lead is twisted around the further longitudinal axis.

10. The semiconductor device of claim 1, wherein the semiconductor device is a through hole semiconductor package.

11. A semiconductor device, comprising:
an encapsulation material at least partially encapsulating a semiconductor component of the semiconductor device; and
a first lead protruding out of the encapsulation material and extending along a longitudinal axis,
wherein a portion of the first lead external to the encapsulation material has a thickness measured in a direction perpendicular to a main surface of the encapsulation material and a width measured in a direction parallel to the main surface of the encapsulation material,
wherein the thickness of the portion of the first lead is greater than the width of the portion of the first lead, and
wherein the first lead is untwisted along the longitudinal axis.

12. The semiconductor device of claim 11, wherein:
the first lead is a power lead mechanically connected to a diepad, and
the first lead and the diepad are made of a single piece of metal.

13. The semiconductor device of claim 12, wherein the first lead and the diepad have a same thickness.

14. The semiconductor device of claim 11, further comprising:
a second lead adjacent to the first lead, wherein a thickness of the first lead is greater than a thickness of the second lead.

15. The semiconductor device of claim 11, wherein the portion of the first lead external to the encapsulation material has the same geometry along its entire length in a longitudinal direction of the first lead.

16. A method for manufacturing a semiconductor device, the method comprising:
providing a lead extending along a longitudinal axis;
twisting a section of the lead around the longitudinal axis, thereby providing a twisted section of the lead; and
at least partially encapsulating a semiconductor component of the semiconductor device in an encapsulation material, wherein the lead at least partially protrudes out of the encapsulation material, wherein:
the twisted section of the lead is encapsulated in the encapsulation material and there is no further twisted section on an outer portion of the lead which protrudes out of the encapsulation material, so that the outer portion of the lead extends along a plane different from a plane along which the most inner portion of the lead extends, or
the twisted section of the lead is external to the encapsulation material and provides an increased clearance distance between a residual dambar portion of the lead and an adjacent lead, wherein the twisted section is located between the encapsulation material and the residual dambar portion.

17. The method of claim 16, wherein twisting the section of the lead is based on a three dimensional coining technique.

18. A method for manufacturing a semiconductor device, the method comprising:
at least partially encapsulating a lead and a semiconductor component of the semiconductor device in an encapsulation material,
wherein a portion of the lead external to the encapsulation material has a thickness measured in a direction perpendicular to a main surface of the encapsulation material and a width measured in a direction parallel to the main surface of the encapsulation material,
wherein the thickness of the portion of the lead is greater than the width of the portion of the lead, and
wherein the lead extends along a longitudinal axis and is untwisted along the longitudinal axis.
